(19) United States
(12) Patent Application Publication
(10) Pub. No.: US 2026/0316215 A1
(43) Pub. Date: Oct. 15, 2026

(54) METHOD OF CHEMICAL MECHANICAL POLISHING A SUBSTRATE USING A CHEMICAL MECHANICAL POLISHING APPARATUS

(71) Applicant: SAMSUNG ELECTRONICS CO., LTD., Suwon-si (KR)

(72) Inventors: Eunkyoung Kim, Suwon-si (KR); Kiho Bae, Suwon-si (KR); Hoyoung Kim, Suwon-si (KR); Boumyoung Park, Suwon-si (KR); Boun Yoon, Suwon-si (KR)

(73) Assignee: SAMSUNG ELECTRONICS CO., LTD., Suwon-si (KR)

(21) Appl. No.: 19/636,615

(22) Filed: Apr. 1, 2026

Related U.S. Application Data
(63) Continuation of application No. 18/296,021, filed on Apr. 5, 2023, now abandoned.

(30) Foreign Application Priority Data
Aug. 12, 2022 (KR) 10-2022-0101170

(51) Int. Cl. B24B 37/005; B24B 57/02; G05D 11/13

(52) U.S. Cl. CPC B24B 37/0056; B24B 57/02; G05D 11/138

(57) ABSTRACT

A method of chemical mechanical polishing a substrate using a chemical mechanical polishing apparatus comprises determining a flow rate of a slurry to be prepared using mixing ratio data of slurry, supplying the slurry stock solution to a mixer of the chemical mechanical polishing apparatus from a slurry stock solution supply device, supplying the hydrogen peroxide, the deionized water, and the additive to the mixer from tanks, mixing, by the mixer, the slurry stock solution, and the hydrogen peroxide, the deionized water, and the additive with each other to prepare the slurry, and supplying the slurry to a polishing pad to chemically and mechanically polish the substrate.

### CROSS-REFERENCE TO RELATED APPLICATION(S)

This application is a Continuation of U.S. patent application Ser. No. 18/296,021, filed on Apr. 5, 2023, which claims priority under 35 U.S.C. § 119 to Korean Patent Application No. 10-2022-0101170 filed on Aug. 12, 2022, in the Korean Intellectual Property Office, the disclosure of which are incorporated herein by reference in their entireties herein.

### TECHNICAL FIELD

The present disclosure relates to a chemical mechanical polishing apparatus and a chemical mechanical polishing method using the same.

### DISCUSSION OF RELATED ART

A chemical mechanical polishing (CMP) process is a process of planarizing a surface of a substrate by combining a mechanical polishing effect using an abrasive with a chemical reaction effect using an acid or a base solution.

Such a CMP process is used to planarize various materials in a process of polishing a silicon oxide layer for the purpose of forming an interlayer dielectric (ILD) or a shallow trench isolation (STI) feature, a tungsten plug, a copper interconnection, or the like.

### SUMMARY

Example embodiments provide a chemical mechanical polishing apparatus for varying a mixing ratio of a slurry depending on process conditions and a chemical mechanical polishing using the same.

According to an example embodiment of the present disclosure, a method of chemical mechanical polishing a substrate using a chemical mechanical polishing apparatus, comprises determining a flow rate of a slurry to be prepared using mixing ratio data of slurry, calculating a flow rate of a slurry stock solution, a flow rate of a hydrogen peroxide, a flow rate of a deionized (DI) water, and a flow rate of an additive for preparing the slurry using the flow rate of the slurry, supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device, supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive, mixing, by the mixer, the slurry stock solution, and the hydrogen peroxide, the deionized (DI) water, and the additive with each other to prepare the slurry, and supplying the slurry to a polishing pad to chemically and mechanically polish the substrate, wherein the supplying of the slurry stock solution to the mixer includes controlling a first valve disposed on the supply line and a first flow rate controller disposed on a first supply pipe connecting the supply line to the mixer, and the supplying of the hydrogen peroxide, the deionized (DI) water, and the additive to the mixer includes controlling a second flow rate controller disposed on a second supply pipe connecting a hydrogen peroxide storage tank to the mixer, a third flow rate controller disposed on a third supply pipe connecting a deionized (DI) water storage tank to the mixer, and a fourth flow rate controller disposed on a fourth supply pipe connecting an additive storage tank to the mixer.

According to an example embodiment of the present disclosure, a method of chemical mechanical polishing a substrate using a chemical mechanical polishing apparatus, comprises determining a flow rate of a slurry to be prepared using mixing ratio data of slurry, calculating a flow rate of a slurry stock solution, a flow rate of a hydrogen peroxide, a flow rate of a deionized (DI) water, and a flow rate of an additive for preparing the slurry using the flow rate of the slurry, supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device, supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive, loading the substrate to be polished on a platen of the chemical mechanical polishing apparatus, mixing, by the mixer, the slurry stock solution, and the hydrogen peroxide, the deionized (DI) water, and the additive with each other to prepare the slurry, and supplying the slurry to a polishing pad to chemically and mechanically polish the substrate, wherein the flow rate of the slurry stock solution, the flow rate of the hydrogen peroxide, the flow rate of the deionized (DI) water, and the flow rate of the additive are based on the mixing ratio data applied to respective substrates on which chemically and mechanically polishing is performed.

According to an example embodiment of the present disclosure, a method of chemical mechanical polishing a substrate using a chemical mechanical polishing apparatus, comprises determining a flow rate of a slurry to be prepared using mixing ratio data of slurry, calculating a flow rate of a slurry stock solution, a flow rate of a hydrogen peroxide, a flow rate of a deionized (DI) water, and a flow rate of an additive for preparing the slurry using the flow rate of the slurry, supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device, supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive, mixing, by the mixer, the slurry stock solution, and the hydrogen peroxide, the deionized (DI) water, and the additive with each other to prepare the slurry, supplying the slurry to a slurry storage tank from the mixer, supplying the slurry to a slurry supply tank from the slurry storage tank, and supplying the slurry from the slurry supply tank to a polishing pad to chemically and mechanically polish the substrate, wherein the flow rate of the slurry stock solution, the flow rate of the hydrogen peroxide, the flow rate of the deionized (DI) water, and the flow rate of the additive are based on the mixing ratio data applied to respective substrates on which chemically and mechanically polishing is performed, and the flow rate of the slurry prepared using mixing ratio data is a flow rate to perform the chemically and mechanically polishing the substrate once.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a schematic diagram of a chemical mechanical polishing system according to an example embodiment of the present disclosure.

FIG. 2 is a block diagram of a chemical mechanical polishing apparatus included in the chemical mechanical polishing system of FIG. 1.

FIG. 3 is a schematic diagram of the chemical mechanical polishing apparatus included in the chemical mechanical polishing system of FIG. 1.

FIG. 4 is a schematic diagram of a chemical mechanical polishing system according to an example embodiment of the present disclosure.

FIG. 5 is a schematic diagram of a chemical mechanical polishing system according to an example embodiment of the present disclosure.

FIG. 6 is a block diagram of a chemical mechanical polishing method according to an example embodiment of the present disclosure.

### DETAILED DESCRIPTION

Hereinafter, example embodiments of the present disclosure will be described with reference to the accompanying drawings.

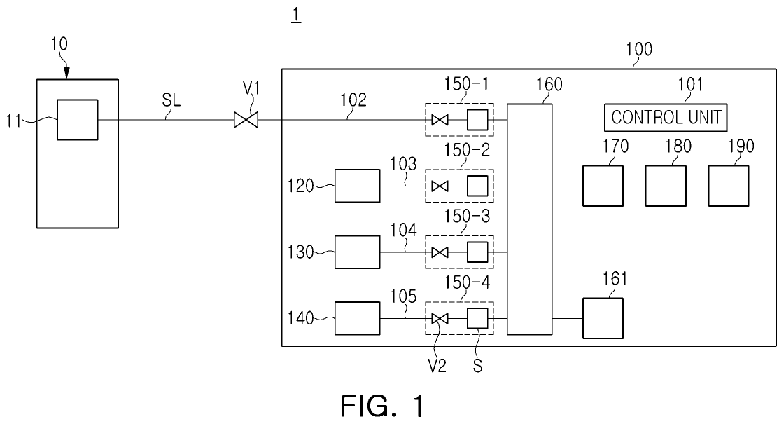

FIG. 1 is a schematic diagram of a first chemical mechanical polishing system 1 according to an example embodiment of the present disclosure.

Referring to FIG. 1, the first chemical mechanical polishing system 1 may include a slurry stock solution supply device 10 supplying a slurry stock solution, a chemical mechanical polishing apparatus 100 generating slurry using the slurry stock solution supplied from the slurry stock solution supply device 10 and performing a chemical mechanical polishing process using the generated slurry. A supply line SL may connect the slurry stock solution supply device 10 and the chemical mechanical polishing apparatus 100 to each other. The first chemical mechanical polishing system 1 according to an example embodiment of the present disclosure is illustrated as having a structure in which a single chemical mechanical polishing apparatus may be connected to a single slurry stock solution supply device. Example embodiments of the present disclosure are not limited thereto and the number of chemical mechanical polishing apparatuses connected to a single slurry stock solution supply device may be varied according to example embodiments of the present disclosure. For example, in the first chemical mechanical polishing system 1, a plurality of chemical mechanical polishing apparatuses may be connected to a single slurry stock solution supply device.

The slurry stock solution supply device 10 may supply the slurry stock solution to the chemical mechanical polishing apparatus 100. The slurry stock solution supply device 10 may include a slurry stock solution storage tank 11. The slurry stock solution storage tank 11 may store the slurry stock solution. The slurry stock solution supply device 10 may be disposed separate from the chemical mechanical polishing apparatus 100. The slurry stock solution supply device 10 may supply the slurry stock solution to the chemical mechanical polishing apparatus 100 through the supply line SL. A valve V1 for controlling a flow rate of the slurry stock solution supplied through the supply line SL may be disposed on the supply line SL.

According to example embodiments of the present disclosure, a supply pump may be used for pressurizing the slurry stock solution. The supply pump may be disposed on the supply line SL.

The slurry stock solution may be used to prepare slurry for use in a chemical mechanical polishing process performed by the chemical mechanical polishing apparatus 100. The slurry may be obtained by diluting the slurry stock solution, and it should be appreciated that a diluent may be mixed with the slurry stock solution. The diluent may include an oxidizer, deionized water (DI water), and an additive. The oxidizer may be, for example, hydrogen peroxide water.

The oxidizer may be provided to control an oxidizing power of the slurry, and may be added such that a pH of the slurry may be maintained in a specific range to satisfy process conditions of a chemical mechanical polishing process to be performed. In some aspects, the oxidizer may tend to decrease in concentration with the lapse of time due to an intrinsic instability of the oxidizer. Accordingly, the oxidizing power of the slurry prepared by mixing the diluent may decrease with the lapse of time, so that the slurry may have a useful lifetime in which the oxidizing power of the slurry satisfies the process conditions. An unused portion of the slurry may be discarded after a predetermined time has passed, for example, after the useful lifetime to ensure that the process conditions may be satisfied.

The first chemical mechanical polishing system 1 according to an example embodiment of the present disclosure may be configured such that a process of mixing the diluent with the slurry stock solution may be performed in the chemical mechanical polishing apparatus 100, thereby reducing a time until the slurry is used in the chemical mechanical polishing process.

Hereinafter, the chemical mechanical polishing apparatus 100 will be described with reference to FIGS. 1 to 3.

The chemical mechanical polishing apparatus 10 may include a mixer 160 mixing a diluent with a slurry stock solution supplied from the slurry stock solution supply device 10 to prepare slurry, a slurry storage unit 170 storing the slurry generated in the mixer 160, and a slurry supply unit 180 supplying the slurry stored in the slurry storage unit 170 to the polishing pad 192. A control unit 101 of the chemical mechanical polishing apparatus 10 may control the mixer 160, the slurry storage unit 170, and the slurry supply unit 180 of the chemical mechanical polishing apparatus 10. The control unit 101 may control the slurry stock solution supply device 10. According to example embodiments of the present disclosure, the chemical mechanical polishing apparatus 100 may further include a cleaning solution supply unit 161. For example, the diluent may include an oxidizer, deionized (DI) water, and an additive, and the oxidizer may be hydrogen peroxide. Example embodiments of the present disclosure are not limited thereto, and the type of the diluent may vary depending on process conditions of a chemical mechanical polishing process. In addition, the chemical mechanical polishing apparatus 100 may have a storage tank supplying the diluent therein. For example, the chemical mechanical polishing apparatus 100 may include a hydrogen peroxide storage tank 120, a DI water storage tank 130, and an additive storage tank 140 therein. The hydrogen peroxide storage tank 120, the DI water storage tank 130, and the additive storage tank 140 may have sizes sufficient to be disposed in the chemical mechanical polishing apparatus 100.

The mixer 160 may mix a diluent with the slurry stock solution, supplied from the slurry stock solution supply device 10, to prepare slurry. The mixer 160 may supply the prepared slurry to the slurry storage unit 170. In an example embodiment of the present disclosure, the number of mixers may correspond to the number of platens 190 on which the chemical mechanical polishing process is performed. In addition, in an example embodiment of the present disclosure, one or more mixers may supply slurry to two or more slurry storage units. In this case, the mixer 160 may sequentially supply the slurry to the two or more slurry storage units, including slurry storage unit 170. The mixer 160 may have a size allowing the mixer 160 to be disposed in the chemical mechanical polishing apparatus 100, and may have an internal space sufficient to generate an amount of slurry sufficient to perform a polishing process for one a semiconductor substrate. The mixer 160 may have an internal space sufficient to generate an amount of slurry sufficient to perform a polishing process for one or more semiconductor substrates.

The mixer 160 may be connected to a first supply pipe 102, a second supply pipe 103, a third supply pipe 104, and a fourth supply pipe 105, to which a slurry stock solution, a hydrogen peroxide solution, DI water, and an additive may be respectively supplied, to receive the slurry stock solution, the hydrogen peroxide solution, the DI water, and the additive. The first supply pipe 102 may be connected to a supply line SL, and the second supply pipe 103 may be connected to a hydrogen peroxide storage tank 120. The third supply pipe 104 may be connected to a DI water storage tank 130, and the fourth supply pipe 105 may be connected to an additive storage tank 140.

A first flow rate control unit 150-1, a second flow rate control unit 150-2, a third flow rate control unit 150-3, and a fourth flow rate control unit 150-4 may be connected to the first supply pipe 102, the second supply pipe 103, the third supply pipe 104, and the fourth supply pipe 105 to control flow rates, respectively. Each of the first flow rate control unit 150-1, the second flow rate control unit 150-2, the third flow rate control unit 150-3, and the fourth flow rate control unit 150-4 may have a valve V2 and a flow meter S. An operation of the valve V2 may be controlled by the control unit 101. A flow rate may be measured by the flow meter S. The measured flow rate may be transmitted to the control unit 101. Accordingly, the control unit 101 may control the first flow rate control unit 150-1, the second flow rate control unit 150-2, the third flow rate control unit 150-3, and the fourth flow rate control unit 150-4 to control the flow rates of the slurry stock solution, the hydrogen peroxide solution, the DI water, and the additives introduced into the mixer 160.

In addition, the control unit 101 may control the first flow rate control unit 150-1, the second flow rate control unit 150-2, the third flow rate control unit 150-3, and the fourth flow rate control unit 150-4 such that a flow rate of the slurry, prepared in the mixer 160, may be the same as a predetermined flow rate. The control unit 101 may control the first flow rate control unit 150-1, the second flow rate control unit 150-2, the third flow rate control unit 150-3, and the fourth flow rate control unit 150-4 using a database including slurry mixing ratio data. The slurry mixing ratio data may be data storing a slurry mixing ratio for a polishing process of each semiconductor substrate, and may be established as a database. According to example embodiments of the present disclosure, the database may be stored in the control unit 101. Accordingly, the control unit 101 may prepare slurry at a slurry mixing ratio appropriate for each semiconductor substrate on which the polishing process is performed using the polishing pad 192 based on the slurry mixing ratio data. The control unit 101 may prepare the slurry such that a flow rate of the prepared slurry is sufficient to perform a current polishing process. For example, the control unit 101 may prepare the slurry such that the flow rate of the prepared slurry is sufficient to perform one polishing process. Accordingly, in the mixer 160, slurry having a mixing ratio appropriate for each semiconductor substrate may be prepared, and the slurry may be prepared only at a flow rate to perform the polishing process of each semiconductor substrate once. As a result, in some example embodiments of the present disclosure, an amount of slurry may be prepared corresponding to the number of semiconductor substrates on which the polishing process is performed in the chemical mechanical polishing apparatus 100, so that the slurry may be prevented from being prepared in an unnecessarily large amount.

The slurry storage unit 170 may store the slurry prepared in the mixer 160. The slurry storage unit 170 may provide the stored slurry to the slurry supply unit 180. The slurry supply unit 180 may have an internal space sufficient to store the slurry prepared in the mixer 160. According to example embodiments of the present disclosure, an outlet 172 for draining the slurry may be formed in the slurry storage unit 170.

According to example embodiments of the present disclosure, a pH sensor 171 for measuring pH of the stored slurry may be disposed in the slurry storage unit 170. The pH sensor 171 may measure the pH of the slurry. The pH sensor 171 may transmit a measured value of the pH of the slurry to the control unit 101. When the pH of the slurry measured by the pH sensor 171 is outside of a reference range, the control unit 101 may open the outlet 172 to drain the slurry stored in the slurry storage unit 170.

The slurry supply unit 180 may supply the slurry, supplied from the slurry storage unit 170, to the polishing pad 192 attached to the platen 190.

The cleaning solution supply unit 161 may be connected to the mixer 160 to supply a cleaning solution to the mixer 160. The cleaning solution supply unit 161 may supply a cleaning solution to the mixer 160 clean slurry remaining in the mixer 160 after a process. For example, the inside of the mixer 160 may be cleaned between chemical mechanical polishing processes. In at least one example, the inside of the mixer 160 may be cleaned between two processes using slurries having different mixing ratios.

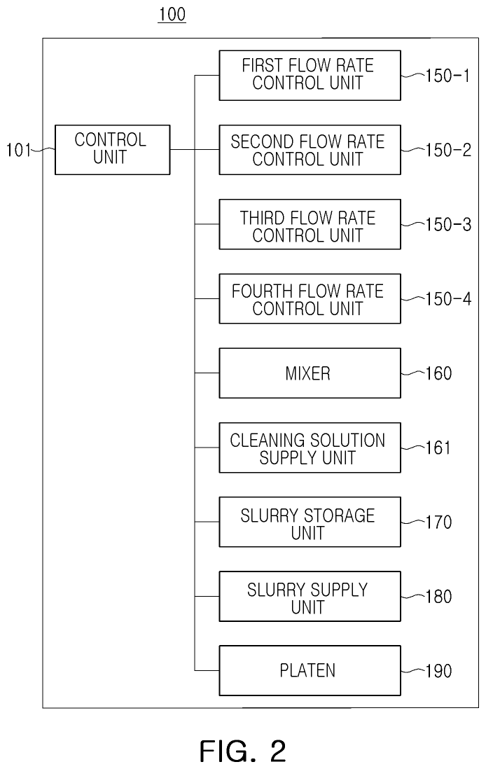

Referring to FIG. 2, the control unit 101 may control an overall operation of the chemical mechanical polishing apparatus 100. For example, the control unit 101 may be implemented as a processor such as a central processing unit (CPU), a graphics processing unit (GPU), a microprocessor, an application specific integrated circuit (ASIC), a field programmable gate arrays (FPGA), or the like. The control unit 101 may include a memory storing various types of data used for an operation of the chemical mechanical polishing apparatus 100. A database including the slurry mixing ratio data may be stored in the memory in advance.

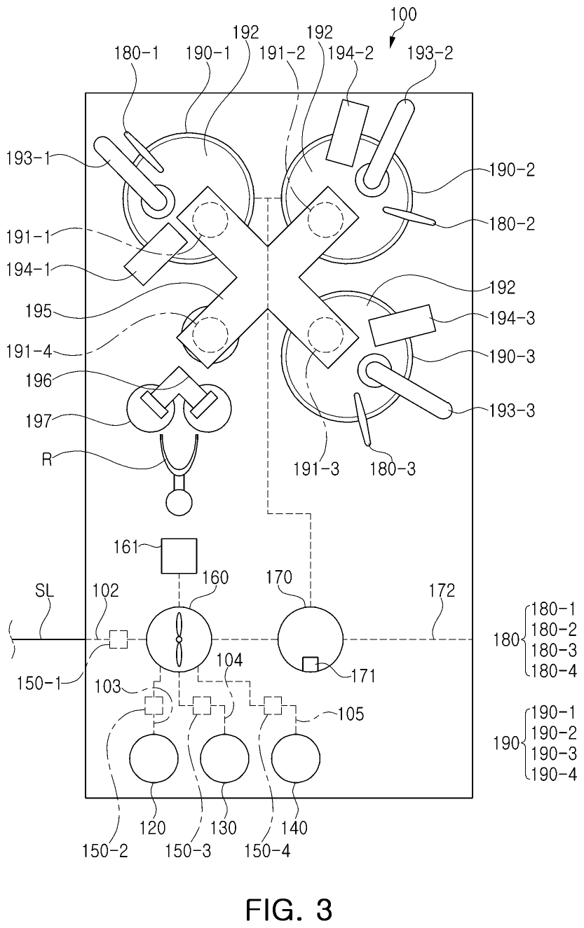

Referring to FIGS. 1 and 3, a platen 190 to which a polishing pad 192 is attached may be disposed on the slurry supply unit 180, and the slurry supply unit 180 may supply the slurry to the polishing pad 192.

FIG. 3 is a detailed schematic diagram of the chemical mechanical polishing apparatus 100 according to an example embodiment of the present disclosure. Referring to FIG. 3, the chemical mechanical polishing apparatus 100 according to an example embodiment of the present disclosure may include first platen 190-1, second platen 190-2, and third platen 190-3, first polishing head 191-1, second polishing head 191-2, third polishing head 191-3, and fourth polishing head 191-4, and first slurry supply unit 180-1, second slurry supply unit 180-2, and third slurry supply unit 180-3. The chemical mechanical polishing apparatus 10 may further include a rotatable multi-head carousel 195, a first conditioner 193-1, a second conditioner 193-2, and a third conditioner 193-3, a semiconductor substrate inverting unit 197, a loading/unloading unit 196, and a robot R.

A polishing pad 192 may be mounted to each of the first platen 190-1, the second platen 190-2, and the third platen 190-3. The first polishing head 191-1, the second polishing head 191-2, and the third polishing head 191-3 and the first slurry supply unit 180-1, the second slurry supply unit 180-2, and the third slurry supply unit 180-3 may be disposed on the first platen 190-1, the second platen 190-2, and the third platen 190-3, respectively.

The first polishing head 191-1, the second polishing head 191-2, the third polishing head 191-3, and the fourth polishing head 191-4 may be attached to the rotatable multi-head carousel 195 to move upwardly from the first platen 190-1, the second platen 190-2, and the third platen 190-3 and the loading/unloading unit 196. The first polishing head 191-1, the second polishing head 191-2, the third polishing head 191-3, and the fourth polishing head 191-4 may be configured to independently perform a lifting operation and a rotation operation. The semiconductor substrate inverting unit 197 may invert and transfer the semiconductor substrate to the loading/unloading unit 196 to polish the semiconductor substrate. The semiconductor substrate inverting unit 197 may invert and transport the semiconductor substrate from the loading/unloading unit 196. The robot R may transfer the semiconductor substrate to be polished to the semiconductor substrate inverting unit 197. The robot R may unload the polished semiconductor substrate from the semiconductor substrate inverting unit 197. The first conditioner 193-1, the second conditioner 193-2, and the third conditioner 193-3 may control a state of the polishing pad 192, for example, to maintain a constant polishing rate.

In the above-configured first chemical mechanical polishing system 1, slurry may be prevented from being unnecessarily prepared and a mixing ratio of the slurry may be varied depending on process conditions.

In the related art, slurry to be supplied to a chemical mechanical polishing apparatus was prepared by diluting a stock solution of the slurry in a slurry supply device disposed in an additional space, spaced apart from the chemical mechanical polishing apparatus, and the prepared slurry was supplied to the chemical mechanical polishing apparatus through a supply line. As described above, the chemical mechanical polishing apparatus received and used the prepared slurry, so that a mixing ratio of the slurry could not be varied depending on process conditions of the chemical mechanical polishing apparatus. In addition, any portion of the prepared slurry which was not used within a certain period of time would be discarded due to an oxidizer mixed during preparation of the prepared slurry. In addition, characteristics of the prepared slurry frequently changed while transferring the prepared slurry through the supply line.

The chemical mechanical polishing apparatus 100 included in the first chemical mechanical polishing system 1 according to an example embodiment of the present disclosure may include a tank in which chemicals mixed with the slurry stock solution are stored, and a mixer mixing a slurry stock solution and the chemicals with each other, and thus slurry may be prepared inside the chemical mechanical polishing apparatus 100. Accordingly, a mixing ratio of the slurry may be varied depending on process conditions of the chemical mechanical polishing apparatus 100. In some example embodiments of the present disclosure, the mixing ratio of the slurry may be varied for a single semiconductor substrate. In addition, since the chemical mechanical polishing apparatus according to an example embodiment of the present disclosure may prepare slurry in an amount sufficient to perform a polishing process on a single semiconductor substrate, and the slurry may be prevented from being prepared in an unnecessarily large amount. In an example embodiment of the present disclosure, slurry may be prepared in an amount sufficient to perform a polishing process on a single semiconductor substrate, and thus the slurry may be prevented from being deteriorated over time in a case where the slurry is prepared as a batch in advance of a polishing process.

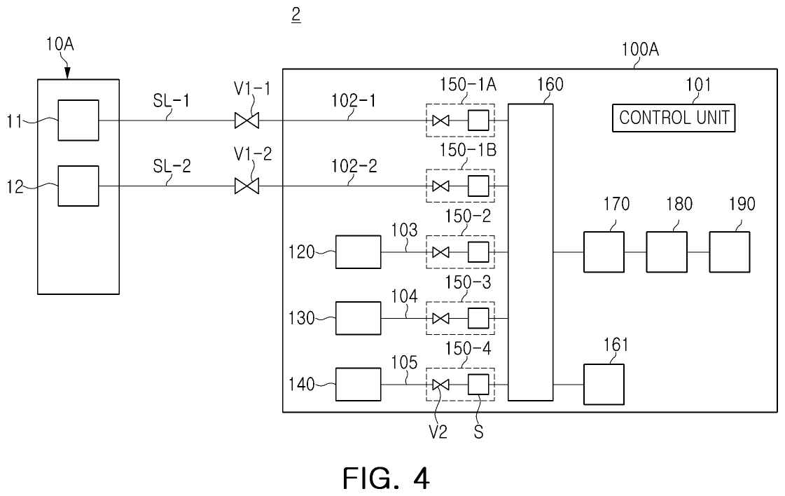

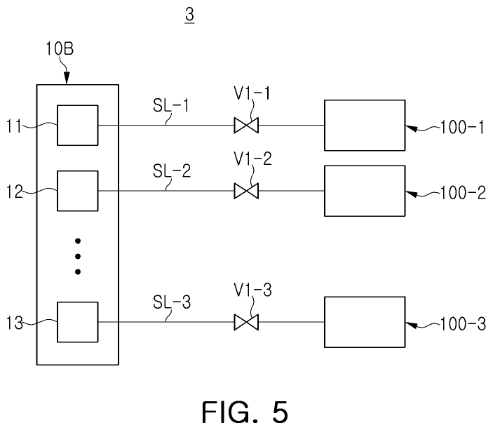

A modified example of a chemical mechanical polishing system according to example embodiments of the present disclosure will be described with reference to FIGS. 4 and 5.

FIG. 4 is a schematic diagram of a second chemical mechanical polishing system 2 according to an example embodiment of the present disclosure. The second chemical mechanical polishing system 2 of FIG. 4 may include a single mixer, such as mixer 160, a first slurry stock solution supply tank 11 and a second slurry stock solution supply tank 12. The other components may be the same as those of the first chemical mechanical polishing system 1, and thus detailed descriptions thereof will be omitted.

Referring to FIG. 4, the second chemical mechanical polishing system 2 according to an example embodiment of the present disclosure may include a slurry stock solution supply device 10A and a chemical mechanical polishing apparatus 100A. The slurry stock solution supply device 10A may include the first slurry stock solution supply tank 11 and the second slurry stock solution supply tank 12. Slurry stock solutions having different compositions may be stored in the first slurry stock solution supply tank 11 and the second slurry stock solution supply tank 12, respectively. The first slurry stock solution supply tank 11 and the second slurry stock solution supply tank 12 may be configured to supply slurries to the mixer 160 through a first supply line SL-1 and a second supply line SL-2, respectively. Valves V1-1 and V1-2 may be disposed on the first supply line SL-1 and the second supply line SL-2 to control flow rates of the slurry stock solutions supplied through the first supply line SL-1 and the second supply line SL-2, respectively. First supply pipe 102-1 and second supply pipe 102-2 may be connected to the first supply line SL-1 and the second supply line SL-2, respectively. The first supply pipe 102-1 and the second supply pipe 102-2 may be connected to the mixer 160. Accordingly, the second chemical mechanical polishing system 2 according to an example embodiment of the present disclosure may change a type of slurry supplied to the mixer 160 depending on process conditions.

FIG. 5 is a schematic diagram of a third chemical mechanical polishing system 3 according to an example embodiment of the present disclosure. The third chemical mechanical polishing system 3 of FIG. 5 may include a plurality of chemical mechanical polishing apparatuses connected to a single slurry stock solution supply apparatus 10. For ease of description, the first slurry stock solution supply tank 11, the second slurry stock solution supply tank 12, and a third slurry stock solution supply tank 13, three supply lines SL-1, SL-2, and SL-3, and three chemical mechanical polishing apparatuses 100-1, 100-2, and 100-3 are illustrated in FIG. 5. Valves V1-1, V1-2, and V1-3 may be disposed on the three supply lines SL-1, SL-2, and SL-3 to control flow rates of slurry stock solutions, respectively. The other components may be the same as those of the first chemical mechanical polishing system 1 according to an example embodiment of the present disclosure, and thus detailed descriptions thereof will be omitted.

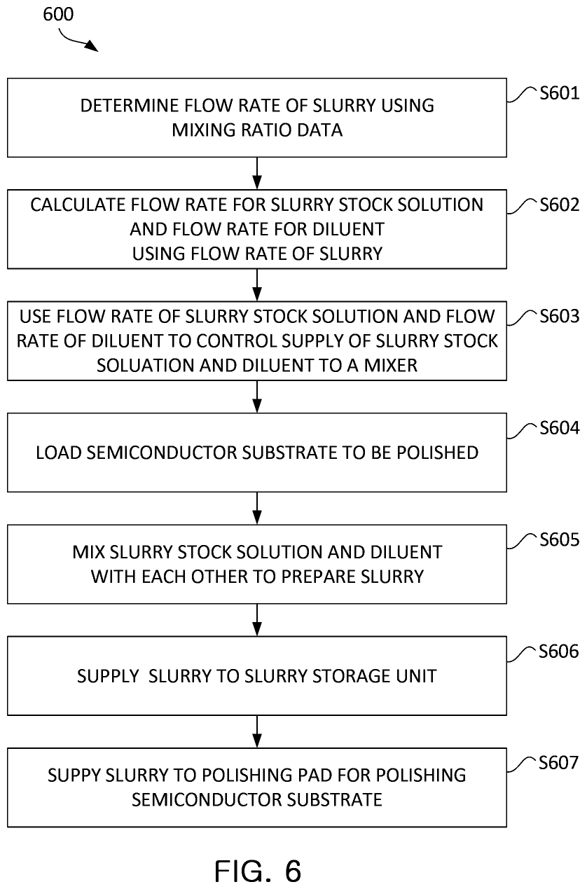

Hereinafter, a chemical mechanical polishing method 600 according to an example embodiment of the present disclosure will be described with reference to FIG. 6. The chemical mechanical polishing method according to an example embodiment of the present disclosure may be performed using the first chemical mechanical polishing system 1 of FIG. 3. A chemical mechanical polishing apparatus 100 included in the first chemical mechanical polishing system 1 will be described with reference to FIGS. 1 and 3. The first chemical mechanical polishing system 1 of FIG. 1 and the chemical mechanical polishing apparatus 100 of FIG. 3 have been described above, and thus a detailed description thereof will be omitted.

At block S601, the control unit 101 may determine a flow rate of slurry to be prepared using a database including a slurry mixing ratio data.

At block S602, the control unit 101 may calculate flow rates of a slurry stock solution, a hydrogen peroxide solution, deionized (DI) water, and an additive for preparing the slurry having the flow rate determined using the database including the slurry mixing ration data.

At block S603, the control unit 101 may control the first flow rate control unit 150-1, the second flow rate control unit 150-2, the third flow rate control unit 150-3, and the fourth flow rate control unit 150-4 based on the calculated flow rates to control flow rates of the slurry stock solution, the hydrogen peroxide solution, the DI water, and the additive, respectively.

At block S604, the control unit 101 may load a semiconductor substrate to be polished on one of the first platens 190-1, the second platen 190-2, and the third platen 190-3.

At block S605, the mixer 160 may mix the supplied slurry stock solution, hydrogen peroxide solution, DI water, and additive with each other to prepare a slurry.

At block S606, the mixer 160 may supply the prepared slurry to the slurry storage unit 170. In this case, pH of the slurry may be measured using a pH sensor 171, and the pH of the slurry measured by the pH sensor 171 may be transmitted to the control unit 101.

At block S607, the prepared slurry may be supplied to the polishing pad 192 attached to the platen 190 through the slurry supply unit 180, and a chemical mechanical polishing process may be performed.

As described above, a chemical mechanical polishing apparatus for varying a mixing ratio of slurry depending on process conditions and a chemical mechanical polishing system using the same may be provided. For example, the process conditions may define conditions for manufacturing an interlayer dielectric (ILD) or a shallow trench isolation (STI) feature, a tungsten plug, a copper interconnection, or the like. Process conditions may be predetermined for other manufacturing processes. Further, process conditions during a single process may be monitoring and varied, for example, based on the measured pH of a slurry.

While example embodiments of the present disclosure have been shown and described above, it will be apparent to those skilled in the art that modifications and variations could be made without departing from the scope of the present disclosure as defined by the appended claims.

What is claimed is:

1. A method of chemical mechanical polishing a substrate using a chemical mechanical polishing apparatus, comprising:
determining a flow rate of a slurry to be prepared using mixing ratio data of slurry;
calculating a flow rate of a slurry stock solution, a flow rate of a hydrogen peroxide, a flow rate of a deionized (DI) water, and a flow rate of an additive for preparing the slurry using the flow rate of the slurry;
supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device;
supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive;
mixing, by the mixer, the slurry stock solution, and the hydrogen peroxide, the deionized (DI) water, and the additive with each other to prepare the slurry; and
supplying the slurry to a polishing pad to chemically and mechanically polish the substrate,
wherein the supplying of the slurry stock solution to the mixer includes controlling a first valve disposed on the supply line and a first flow rate controller disposed on a first supply pipe connecting the supply line to the mixer, and
the supplying of the hydrogen peroxide, the deionized (DI) water, and the additive to the mixer includes controlling a second flow rate controller disposed on a second supply pipe connecting a hydrogen peroxide storage tank to the mixer, a third flow rate controller disposed on a third supply pipe connecting a deionized (DI) water storage tank to the mixer, and a fourth flow rate controller disposed on a fourth supply pipe connecting an additive storage tank to the mixer.

2. The method of claim 1, further comprising loading the substrate to be polished on a platen of the chemical mechanical polishing apparatus before the mixing of the slurry stock solution, and the hydrogen peroxide, the deionized (DI) water, and the additive with each other to prepare the slurry.

3. The method of claim 1, wherein the supplying of the slurry to the polishing pad includes:
supplying the slurry to a slurry storage tank of the chemical mechanical polishing apparatus from the mixer;
supplying the slurry to a slurry supply tank of the chemical mechanical polishing apparatus from the slurry storage tank; and
supplying the slurry from the slurry supply tank to the polishing pad to chemically and mechanically polish the substrate.

4. The method of claim 3, further comprising performing cleaning the mixer after the supplying the slurry to the slurry storage tank of the chemical mechanical polishing apparatus from the mixer.

5. The method of claim 3, wherein the slurry storage tank further comprises a pH sensor configured to measure pH of the slurry.

6. The method of claim 5, further comprising controlling an outlet of the slurry storage tank to drain the slurry stored in the slurry storage tank, when the pH of the slurry measured by the pH sensor is outside of a reference range.

7. The method of claim 5, wherein the supplying of the slurry to the polishing pad includes supplying the slurry to the polishing pad disposed on a platen of the chemical mechanical polishing apparatus from the slurry supply tank.

8. The method of claim 1, wherein the flow rate of the slurry stock solution, the flow rate of the hydrogen peroxide, the flow rate of the deionized (DI) water, and the flow rate of the additive are based on the mixing ratio data applied to respective substrates on which chemically and mechanically polishing is performed.

9. The method of claim 8, wherein the flow rate of the slurry prepared using mixing ratio data is a flow rate to perform the chemically and mechanically polishing the substrate once.

10. The method of claim 1, wherein each of the first flow rate controller, the second flow rate controller, the third flow rate controller, and the fourth flow rate controller includes a valve and a flow meter between the valve and the mixer.

11. The method of claim 10, wherein the first supply pipe is between the first valve disposed on the supply line and the valve of the first flow rate controller.

12. A method of chemical mechanical polishing a substrate using a chemical mechanical polishing apparatus, comprising:
determining a flow rate of a slurry to be prepared using mixing ratio data of slurry;
calculating a flow rate of a slurry stock solution, a flow rate of a hydrogen peroxide, a flow rate of a deionized (DI) water, and a flow rate of an additive for preparing the slurry using the flow rate of the slurry;
supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device;
supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive;
loading the substrate to be polished on a platen of the chemical mechanical polishing apparatus;
mixing, by the mixer, the slurry stock solution, and the hydrogen peroxide, the deionized (DI) water, and the additive with each other to prepare the slurry; and
supplying the slurry to a polishing pad to chemically and mechanically polish the substrate,
wherein the flow rate of the slurry stock solution, the flow rate of the hydrogen peroxide, the flow rate of the deionized (DI) water, and the flow rate of the additive are based on the mixing ratio data applied to respective substrates on which chemically and mechanically polishing is performed.

13. The method of claim 12, wherein the flow rate of the slurry prepared using mixing ratio data is a flow rate to perform the chemically and mechanically polishing the substrate once.

14. The method of claim 12, wherein
the supplying of the slurry stock solution to the mixer includes controlling a first valve disposed on the supply line and a first flow rate controller disposed on a first supply pipe connecting the supply line to the mixer, and
the supplying of the hydrogen peroxide, the deionized (DI) water, and the additive to the mixer includes controlling a second flow rate controller disposed on a second supply pipe connecting a hydrogen peroxide storage tank to the mixer, a third flow rate controller disposed on a third supply pipe connecting a deionized (DI) water storage tank to the mixer, and a fourth flow rate controller disposed on a fourth supply pipe connecting an additive storage tank to the mixer.

15. The method of claim 12, wherein the supplying of the slurry to the polishing pad includes:
supplying the slurry to a slurry storage tank of the chemical mechanical polishing apparatus from the mixer;
supplying the slurry to a slurry supply tank of the chemical mechanical polishing apparatus from the slurry storage tank; and
supplying the slurry from the slurry supply tank to the polishing pad to chemically and mechanically polish the substrate.

16. The method of claim 15, wherein the slurry storage tank further comprises a pH sensor configured to measure pH of the slurry.

17. The method of claim 16, further comprising controlling an outlet of the slurry storage tank to drain the slurry stored in the slurry storage tank, when the pH of the slurry measured by pH sensor is outside of a reference range.

18. The method of claim 15, further comprising performing cleaning the mixer after the supplying the slurry to the slurry storage tank of the chemical mechanical polishing apparatus from the mixer.

19. A method of chemical mechanical polishing a substrate using a chemical mechanical polishing apparatus, comprising:
determining a flow rate of a slurry to be prepared using mixing ratio data of slurry;
calculating a flow rate of a slurry stock solution, a flow rate of a hydrogen peroxide, a flow rate of a deionized (DI) water, and a flow rate of an additive for preparing the slurry using the flow rate of the slurry;
supplying the slurry stock solution to a mixer of the chemical mechanical polishing apparatus from a slurry stock solution supply device disposed outside the chemical mechanical polishing apparatus through a supply line connecting the chemical mechanical polishing apparatus to the slurry stock solution supply device;
supplying the hydrogen peroxide, the deionized (DI) water, and the additive to the mixer from tanks disposed inside the chemical mechanical polishing apparatus through a plurality of supply pipes connecting the mixer to the tanks configured to store at least one of the hydrogen peroxide, the deionized (DI) water, and the additive;
mixing, by the mixer, the slurry stock solution, and the hydrogen peroxide, the deionized (DI) water, and the additive with each other to prepare the slurry;
supplying the slurry to a slurry storage tank from the mixer;
supplying the slurry to a slurry supply tank from the slurry storage tank; and
supplying the slurry from the slurry supply tank to a polishing pad to chemically and mechanically polish the substrate,
wherein the flow rate of the slurry stock solution, the flow rate of the hydrogen peroxide, the flow rate of the deionized (DI) water, and the flow rate of the additive are based on the mixing ratio data applied to respective substrates on which chemically and mechanically polishing is performed, and
the flow rate of the slurry prepared using mixing ratio data is a flow rate to perform the chemically and mechanically polishing the substrate once.

20. The method of claim 19, further comprising loading the substrate to be polished on a platen of the chemical mechanical polishing apparatus before the mixing of the slurry stock solution, and the hydrogen peroxide, the deionized (DI) water, and the additive with each other to prepare the slurry.
